(19) United States
(12) Patent Application Publication
(10) Pub. No.: US 2006/0284252 A1
(43) Pub. Date: Dec. 21, 2006

(54) Process for holding strain in an island etched in a strained thin layer and structure obtained by implementation of this process

(76) Inventors: Alice Boussagol, Brignoud (FR); Ian Cayrefourcq, St. Nazaire Les Eymes (FR)

Correspondence Address: WINSTON & STRAWN LLP, 1700 K STREET, N.W., WASHINGTON, DC, 20006, US

(21) Appl. No.: 11/214,590

(22) Filed: Aug. 29, 2005

(30) Foreign Application Priority Data
Jun. 15, 2005 (FR) 0506047

(51) Int. Cl. H01L 27/12

(52) U.S. Cl. 257/347

(57) ABSTRACT

The invention relates to structures useful for the manufacture of electronic components, which comprise a substrate, a strain holding layer, and a layer of a strained semiconducting material. These structures are particularly useful where islands are later formed in the strained semiconducting material because the strain holding layer limits relaxation of stress in the islands. This invention also relates to processes for making a these structures.

### FIELD OF THE INVENTION

The field of the invention related to structures comprising a substrate with a thin layer of a strained semiconducting material, the thin layer acting as an active layer for the formation of electronic components.

### BACKGROUND

Semiconductor structures a strained active layer on the surface of a substrate have advantageous electrical properties. Since the crystalline network of the electrically active layer is strained, the mobility of electric charges (electrons, holes) is effectively increased over the entire active layer as compared to an unstrained layer. The result is an increase of the order of 20 to 30% in the performance of the transistors that will be formed from the strained layer.

It is known that the thickness of the strained layer is limited to a critical thickness beyond which plastic relaxation of the strain is observed because of the formation of dislocation type defects. Care must be taken in this invention not to form a thin layer for which the thickness exceeds the critical thickness beyond which plastic relaxation is observed by the formation of dislocations.

For example, an sSi layer formed on a subjacent layer of relaxed SiGe containing 20% of Ge may have a thickness of the order of 20 nm under standard deposition temperature conditions (500° C. to 800° C.) without any dislocations being formed. A layer of sSi formed on a layer of SiO₂, for example using a layer transfer technology, for standard deposition temperatures about 700° C. may be thickened to about 70 to 100 nm, without the excessive formation of dislocations.

In order to manufacture electronic components, the thin layer is typically etched according to a particular pattern to form a set of islands made from the strained semiconducting material. It is possible that elastic relaxation of the stress will take place during the etching operation in which the islands will be formed (in other words at least partial relaxation of the stress without the formation of dislocations). Relaxation of the stress may vary as a function of the thickness of the thin layer or as a function of the size of the island.

In other words, there is a risk that the stress in the island will no longer be the same as the stress in the thin layer from which it was formed. In particular, when the stress is particularly homogeneous within the original layer, there is a possibility that the stress will no longer be homogeneous within the island.

Substrate manufacturers have limited the thickness of strained thin layers in the past, to reduce the risk of this stress being relaxed.

However, there is a need for semiconductor structures with thicker strained layers than heretofore, particularly for the formation of electronic components for optics according to partially depleted (PD) architectures.

More generally, it is desirable to minimise relaxation of the stress following the etching operation for the formation of islands, and therefore also minimise the risk of causing degradation of the performances of electronic components made therefrom.

### SUMMARY OF THE INVENTION

The purpose of the invention is to satisfy this need for a technique (or techniques or a process or processes) to avoid relaxation of stress in the islands formed by etching a thin layer made of a strained semiconducting material.

Non-limiting examples of structures made by these techniques include SGOI (Strained Silicon on SiGe on Insulator) structures comprising a substrate, an insulating layer, a relaxed SiGe layer and a thin strained Si layer on the relaxed SiGe layer, or SSOI (Strained Silicon on Insulator) structures comprising a substrate, an insulating layer and a thin strained silicon layer directly on the insulating layer.

These structures are advantageous for use in manufacturing electronic components that have a set of islands made from the strained semiconducting material. Therefore, according to one aspect of the invention, these techniques include a step of forming a strain holding layer on the thin layer designed to limit relaxation of the stress of the semiconducting material in the islands formed from the thin layer during the subsequent manufacturing step.

More particularly, this invention can advantageously be used for applications in the process for manufacturing integrated circuits (and particularly for manufacturing CMOS components) during which a thick oxide layer is formed conventionally (by oxidation of the substrate, typically made of silicon) or a layer made of dielectric material is deposited on the substrate (for example in the case in which the substrate is of the sSOI type), these layers typically acting as a grid oxide or a dielectric layer. Indeed, the strain holding layer may perform this role of a thick oxide layer/dielectric layer, while also maintaining uniform stress in the thin layer that will act as the conducting area.

Some preferred but non-limiting aspects of these techniques or processes include:
forming a strain holding layer on the strained thin layer with a thickness approximately equal to the thickness of the strained thin layer;
forming a strain holding layer comprising SiO₂;
forming a strain holding layer comprising Si₃N₄.

According to another aspect, the invention includes processes for forming an island of a thin layer made of a strained semiconducting material by first forming a strain holding layer on the thin layer, the strain holding layer being adapted to limit the relaxation of the stress of the semiconducting material in the island, and second by etching the thin layer and the strain holding layer so that the island formed thereby is covered by a part of the strain holding layer.

The etching step may be carried out such that the dimensions of the island in the strain directions are approximately twice the thickness of the thin layer from which it is formed.

The formation step may be carried out so as to form a strain holding layer on the strained thin layer, the thickness of which is equal to at least the thickness of the strained thin layer.

This invention also includes structures made by the processes of the invention.

### BRIEF DESCRIPTION OF THE DRAWING FIGURES

Other aspects, advantages and purposes of this invention will become clear after reading the following detailed description of preferred embodiments of the invention with reference to the attached drawings on which:

FIG. 1 illustrates a structure comprising a strained thin layer starting from which a set of islands is formed;

FIG. 2 illustrates an SeOI (Semiconductor On Insulator) structure;

FIG. 3 illustrates the symmetry of the relaxation phenomenon when the technique used to form the strained thin layer creates a stress with bi-axial symmetry;

FIG. 4 illustrates a graph showing the variation of the stress along the upper edge of an island not covered by a strain holding layer for different thicknesses of the island;

FIG. 5 illustrates a graph showing the lateral shrinkage of an island not covered by a strain holding layer as a function of the thickness of the island;

FIG. 6 illustrates a diagram showing the shrinkage observed by lateral displacement of the edges of an island not covered by a strain holding layer;

FIG. 7 illustrates a graph showing the relative shrinkage of an island not covered by a strain holding layer as a function of the length of the side of the island;

FIG. 8 illustrates a graph showing the variation of the stress along the upper edge of an island not covered by a strain holding layer for different lengths of the side of the island;

FIG. 9 illustrates the different steps of an embodiment of a process according to the invention;

FIGS. 10 and 11 illustrate the shrinkage observed after etching a strained thin layer on which strain holding layers made of SiO₂ and Si₃N₄ respectively have been previously formed;

FIGS. 12 and 13 illustrate the variation of the stress along the top edge of an island for different embodiments of a process according to the invention.

### DETAILED DESCRIPTION OF PREFERRED EMBODIMENTS

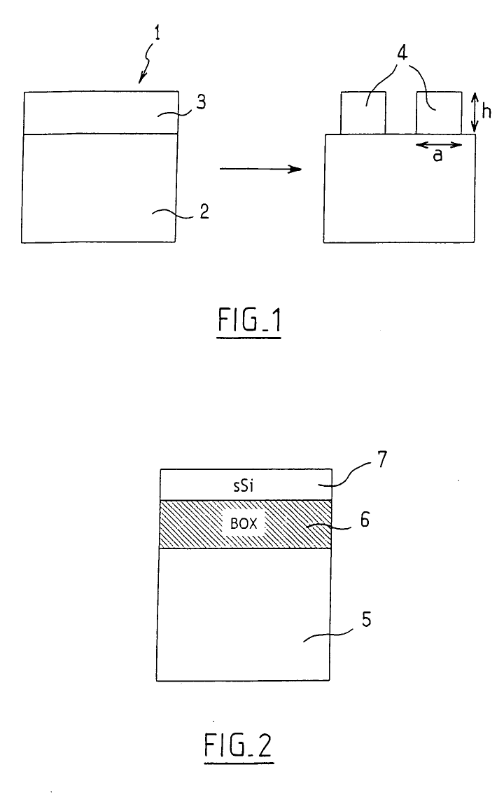

With reference to FIG. 1, the figure shows a structure 1 comprising a substrate 2 and a thin layer 3 made of a strained semiconducting material on the substrate 2. During a step of manufacturing electronic components, a set of islands 4 is formed from the thin strained semiconducting layer 3. The islands 4 will form conducting regions for electronic components. The islands 4 are typically formed by etching the thin layer 3 in a particular pattern. It should be noted that this etching may be chemical etching or Reactive Ion Etching (RIE).

The following description is initially intended to analyse the stress relaxation in the islands following etching the thin layer during the manufacturing of electronic components.

Etching of the strain layer was simulated by making a finite element model so as to quantify stress relaxation phenomena within the layer “cut-out” by etching the thin layer to form an island. More precisely, this simulation studies the relaxation within the island as a function of the variation of two dimensions: the height h and the length a of the island.

The structure studied in the context of this simulation is more precisely an SeOI (Semiconductor On Insulator) type structure comprising a thin layer made of a strained semiconducting material transferred using a SMART-CUT® type layer transfer process onto an insulating layer deposited on a silicon basic substrate.

Further details about the SMART-CUT® process can be found in the “Silicon-On-Insulator Technology: Materials to VLSI, 2^{nd} Edition”, by Jean-Pierre Colinge from “Kluwer Academic Publishers”, P. 50 and 51.

More precisely, the structure studied comprises (see FIG. 2):
a basic substrate 5 made of silicon <100>;
an insulating layer 6 made of Si0₂ (also called a Buried Oxide (BOX) layer), with a thickness of between 800 and 2000 Angstroms and preferably about 1450 Angstroms;
a strained layer 7, for example a strained silicon layer (sSI) or a strained silicon Germanium SiGe layer with a mesh parameter mismatch of the order of 0.78% compared to the same relaxed material and with a uniform stress. The sSI layer can be formed on a relaxed crystalline germ layer of the SiGe type with 20% Ge. The uniform stress can be, for example, a biaxial stress of the order of 1.4 Giga Pascal (Gpa), within the strained layer.

The mechanical behaviour of the sSI strained layer has been modelled using the linear elastic theory and the stress variation has been studied using the finite element calculation method.

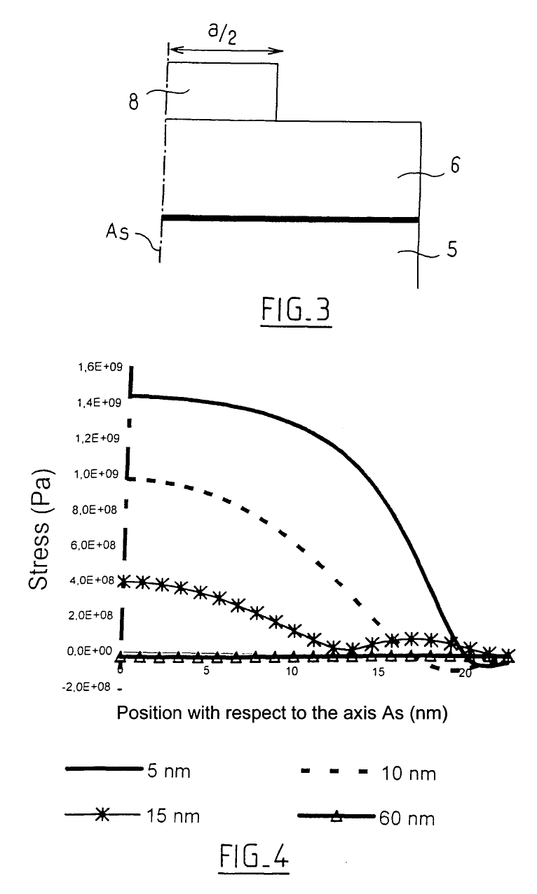

In the context of this simulation, the islands are supposed modelled with as parallelograms with a height h and a square base with side a (see FIG. 1). This high degree of symmetry together with the bi-axial symmetry of the stress in the layer studied here allows the problem to be reduced to two dimensions as shown in FIG. 3 (in which the reference A_{S} indicates the axis of symmetry). FIG. 3 illustrates the strained silicon island 8 obtained by etching a sSI layer 7 (reference 7 in FIG. 2).

It should be noted here that deposition of an Si thin layer by epitaxy on another material of the SiGe type creates a stress with biaxial symmetry (and particularly a tension stress) in the thin layer of strained Si. However, other techniques for the formation of strained thin layers could create other types of stress and particularly a stress with uniaxial symmetry. And the invention is in no way limited to thin layers with biaxial stress, but includes any type of strained thin layer and particularly thin layers with uni-axial stress.

FIG. 4 illustrates the variation of stress along the upper edge of the island (starting from the central part and moving towards its free edge) for different thicknesses h of the island. The stress is seen to be reduced as the distance from the periphery of the island reduces. The stress values are also seen to be reduced as a function of the thickness of the island, which is determined by the thickness of the strained thin layer from which the island was formed.

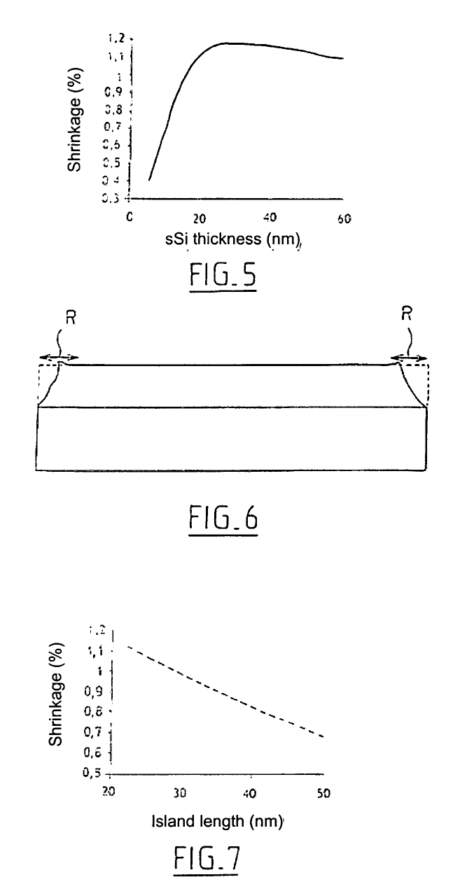

FIG. 5 illustrates a graph showing the shrinkage of the island as a function of the thickness h of the island (in other words the thickness of the sSI layer from which the island was formed). It should be noted that relaxation of the stress in the sSI island causes shrinkage of the dimension a/2. It should be noted also that this shrinkage relative to the dimension a/2 decreases as the thickness of the island decreases.

FIG. 6 diagrammatically illustrates this shrinkage by lateral displacement (see arrows R) of the edges of the island.

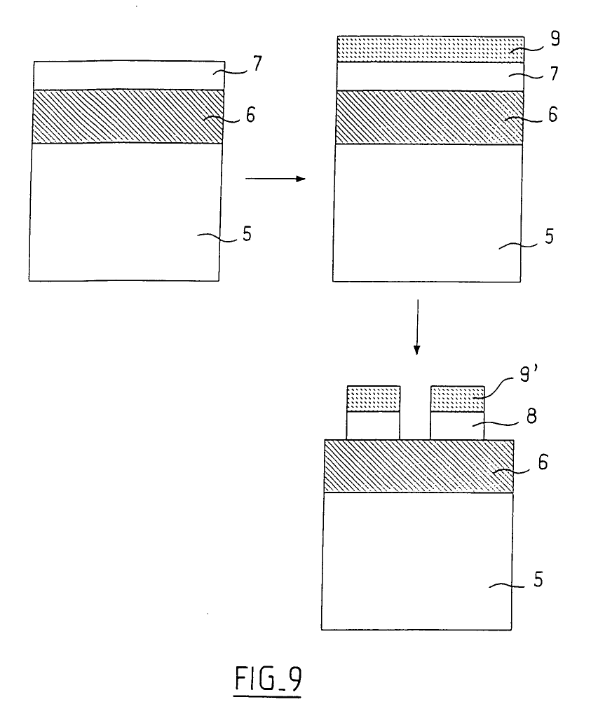

FIG. 7 illustrates a graph showing the variation in the relative shrinkage of the island as a function of the length of the island. This graph shows that the relative shrinkage is greater for small patterns.

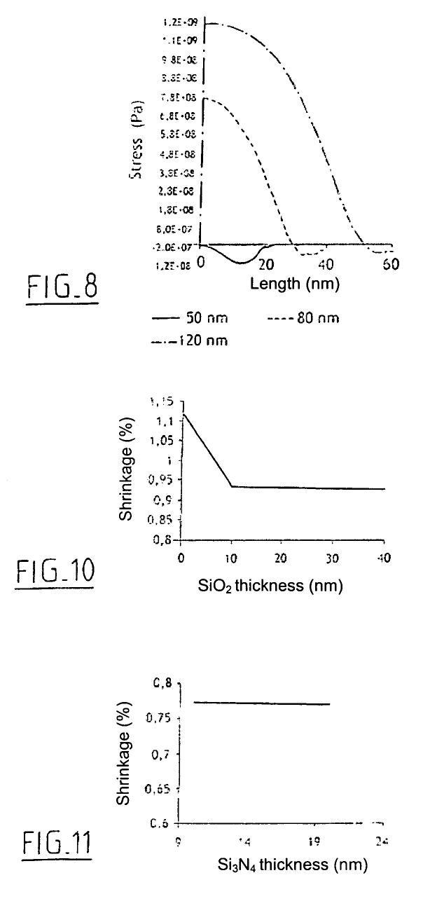

FIG. 8 illustrates the stress along the top edge of the island for island lengths a equal to 50, 80 or 120 nm respectively. It can be seen that the stress reduces with the length of the island.

In summary, the above graphs show that the formation of islands is accompanied by stress variation and lateral displacement problems that could reduce performances of the electronic components that will then be formed.

With reference to FIG. 9, the invention solves these problems by forming a strain holding layer 9 on the strained thin layer 7, the strain holding layer being adapted to limit the stress relaxation of the semiconducting material in the islands 8 formed from the strained thin layer 7 during circuit manufacturing. The thickness of the layer 9 deposited on the thin layer 7 is typically between 10 and 30 nm.

The thin layer 7 is etched through the strain holding layer 9 to form islands of strained material having a selected pattern. After etching, the islands 8 will thus each be covered by a layer 9′ derived from the strain holding layer 9.

The step for formation of the strain holding layer 9 may consist of forming the layer 9 over all or part of the surface of the strained thin layer 7. The formation step is typically carried out by depositing the layer 9 on all or part of the thin layer 7. This formation is not limited by the thickness of the strained thin layer 7. Thus, it is possible to form the layer 9 on a relatively thin layer 7, or on a thick layer.

The strain holding layer 9 may be a layer made of a rigid material, indifferently relaxed or stressed. An SiO₂ layer is an example of a strain holding layer made of a relaxed rigid material. A layer of Si₃N₄ is an example of a strain holding layer made of a strained rigid material. It should be noted that the deposition techniques that can be used to form an Si₃N₄ layer on the thin layer may form a layer of Si₃N₄ stressed in tension or compression. Furthermore, the deposition of a Si₃N₄ layer stressed in compression may be particularly advantageous when the objective is to hold the stress within a thin layer stressed in tension (such as a strained Si layer formed on SiGe).

Stress has been studied in the sSI island for different thicknesses and lengths of the strain holding layer 9. The thickness of the island studied is 20 nm and its square base is 90 nm long (a/2=45 nm).

FIGS. 10 and 11 illustrate shrinkage observed after etching the strained thin layer on which a strain holding layer had previously been deposited. FIG. 10 illustrates shrinkage as a function of the thickness of a strain holding layer made of SiO₂. FIG. 11 illustrates shrinkage as a function of the thickness of a strain holding layer made of Si₃N₄.

In detail, these figures illustrate the maximum observed shrinkage (globally observed at half of thickness of the island). It is observed that shrinkage is a function of the mechanical properties of the material from which the strain holding layer is made. In particular, the elastic properties of the strain holding layer have a direct influence on the thickness that must be deposited to retain a given strain quantity and to limit shrinkage of the island.

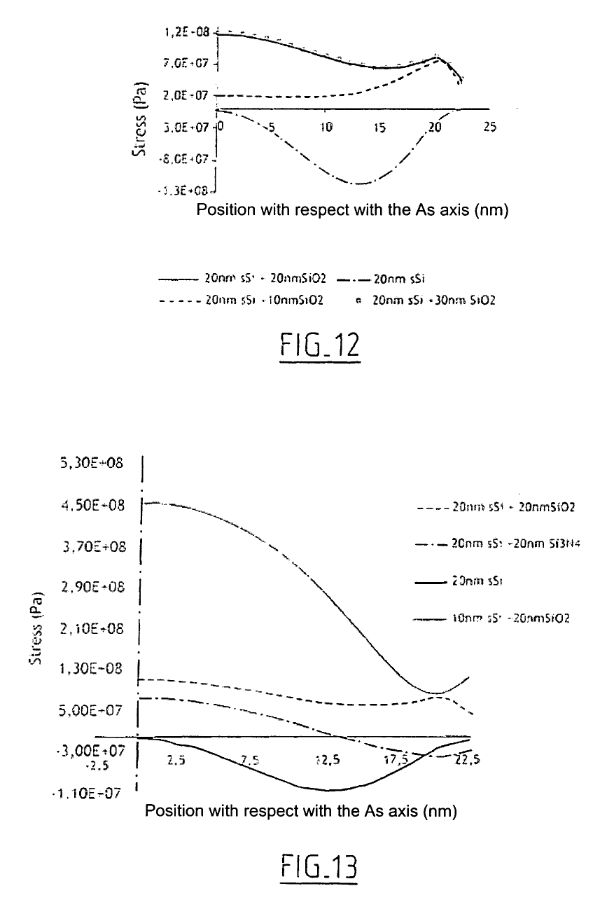

FIG. 12 illustrates the stress variation along the upper edge of the island in the following configurations:
a thin layer of 20 nm thick sSI on which a strain holding layer was not formed before an island with a 45 nm side square pattern was formed (a/2=22.5 nm);
a thin layer of 20 nm thick sSI on which a layer of SiO₂ was deposited before forming an island with a 45 nm side square pattern (a/2=22.5 nm), the thickness of the SiO₂ layer being either:
   10 nm,
   20 nm, or
   30 nm.

FIG. 13 further illustrates the stress variation along the upper edge of the island in the following configurations:
a thin layer of 10 nm thick sSI on which a 20 nm thick SiO₂ layer was deposited before an island with a 45 nm side square pattern was formed (a/2=22.5 nm);
a thin layer of 20 nm thick sSI on which a strain holding layer was not formed before an island with a 45 nm side square pattern was formed (a/2=22.5 nm);
a thin layer of 20 nm thick sSI on which a layer of the following was deposited before forming an island with a 45 nm side square pattern (a/2=22.5 nm), either:
   20 nm thick SiO₂, or
   20 nm thick Si₃N₄.

FIGS. 12 and 13 illustrate how this invention advantageously maintains the stress in an island of strained semiconducting material (in this case silicon) formed from a thin layer of the strained semiconducting material. Furthermore, it can be seen in FIGS. 9 to 12 that there is an optimum thickness of the strain holding layer above which no improvement is observed.

It can be seen from the various figures, and particularly the comparison of FIGS. 4 and 12, that this invention maintains stress levels on the island and particularly on its edges. The stress level is thus globally homogeneous within the thin layer covered by a strain holding layer according to the invention. Therefore, since the thin layer is intended to form a conduction area within an electronic component, the invention can be used to maintain a globally homogeneous stress level within the conducting area.

It can be concluded from the above that before etching, formation of a strain holding layer can limit the relaxation phenomenon. The efficiency of this strain holding layer is directly related to its elastic properties (type of material from which this layer is formed) and its geometric dimensions.

The following conclusions in particularly can be drawn from an examination specifically of FIG. 12. The maximum stress in an island can be particularly maintained by etching of the thin layer preferentially such that the dimensions of the island in the stress directions are approximately twice as great as its thickness h (which is also the thickness of the thin layer from which it is formed). For example, an island can be etched so that it has a square base for which the side a is approximately twice its thickness h. The stress directions are typically, in the case of a parallelepiped shaped island, along the width and length of the base, or, for an ellipse shaped island, along the dimensions of the small axis and the large axis.

Furthermore, the step for the formation of a strain holding layer on the strained layer is preferably done such that the thickness of the strain holding layer is approximately equal to at least the thickness h of the island (in other words the thickness of the thin layer from which the island is formed). Also, the invention is not limited to the formation of a single strain holding layer but it also includes the deposition of a multilayer structure capable of acting as a structure holding layer, onto the strained thin layer.

The invention described and claimed herein is not to be limited in scope by the preferred embodiments herein disclosed, since these embodiments are intended as illustrations of several aspects of the invention. Any equivalent embodiments are intended to be within the scope of this invention. Indeed, various modifications of the invention in addition to those shown and described herein will become apparent to those skilled in the art from the foregoing description. Such modifications are also intended to fall within the scope of the appended claims.

A number of references are cited herein, the entire disclosures of which are incorporated herein, in their entirety, by reference for all purposes. Further, none of these references, regardless of how characterized above, is admitted as prior to the invention of the subject matter claimed herein.

What is claimed is:

1. A method for making a semiconductor substrate comprising a layer of a strained semiconducting material, the method comprising:
forming a strain holding layer on the strained semiconducting layer on the substrate,
wherein the strain holding layer is adapted to limit strain relaxation in the strained semiconducting material or a portion thereof.

2. The method of claim 1, wherein the strain holding layer has a thickness approximately equal to or greater than the thickness of the strained semiconducting layer.

3. The method of claim 1, wherein the strain holding layer comprises silicon dioxide (SiO₂).

4. The method of claim 1, wherein the strain holding layer comprises silicon nitride (Si₃N₄).

5. The method of the claim 4, wherein the strained semiconducting layer comprises a silicon layer having tension stresses, and wherein the strain holding layer comprises a silicon nitride (Si₃N₄) layer having compression stresses.

6. A method for making a semiconductor substrate comprising a layer of a strained semiconducting material, the method comprising:
forming a strain holding layer on the strained semiconducting layer on the substrate, and
etching the substrate to form one or more island substructures which comprise portions of the strained semiconducting layer and overlying portions the strain holding layer and,
wherein the strain holding layer is adapted to limit strain relaxation in the islands substructures.

7. The method of claim 6, wherein the strain holding layer comprises silicon dioxide (SiO₂).

8. The method of claim 6, wherein the strain holding layer comprises silicon nitride (Si₃N₄).

9. The method of the claim 8, wherein the strained semiconducting layer comprises a silicon layer having tension stresses, and wherein the strain holding layer comprises a silicon nitride (Si₃N₄) layer having compression stresses.

10. The method of claim 6, wherein at least one island substructure comprises a dimension in at least one direction of strain that is approximately twice the thickness of the strained semiconducting layer.

11. The method according claim 6, wherein at least one island substructure comprises a square base with a side that is approximately twice the thickness of the strained semiconducting layer.

12. The method of claim 6, wherein the strain holding layer has a thickness approximately equal or greater than to the thickness of the strained semiconducting layer.

13. A semiconductor structure comprising:
a substrate,
a layer of a strained semiconducting material on the substrate, and
a strain holding layer on the strained layer,
wherein the strain holding layer is adapted to limit strain relaxation in the strained semiconducting material of portions thereof.

14. The structure of claim 13, wherein the strained semiconducting layer comprises a semiconductor-on-insulator (SeOI) structure.

15. The structure of claim 13, wherein the strain holding layer comprises silicon dioxide (SiO₂).

16. The structure of claim 13, wherein the strain holding layer comprises silicon nitride (Si₃N₄).

17. The structure of claim 13, wherein the strain holding layer has a thickness approximately equal or greater than to the thickness of the strained semiconducting layer.

18. The structure of claim 13, wherein the strained semiconducting layer comprises a silicon layer having tension stresses, and wherein the strain holding layer comprises a silicon nitride (Si₃N₄) layer having compression stresses.

19. The structure of claim 13, wherein a portion of the strained semiconducting layer forms at least one island substructure on the substrate.

20. The structure of claim 19 wherein at least one island substructure is at least partially covered by the strain holding layer.

21. The structure of claim 19, wherein at least one island substructure comprises a length in at least one direction of strain that is approximately twice the thickness of the strained semiconducting layer.

22. The structure of claim 19, wherein at least one island substructure comprises a square base with a side that is approximately twice the thickness of the strained semiconducting layer.

23. The method of claim 6 wherein at least a part of at least one island substructure is covered by the strain holding layer.
